(19) United States
(12) Patent Application Publication
(10) Pub. No.: US 2005/0069651 A1
(43) Pub. Date: Mar. 31, 2005

(54) Plasma processing system

(75) Inventors: Hideaki Miyoshi, Nirasaki-shi (JP); Gemunu Ranjith Dharmasena, Nirasaki-shi (JP); Tsutomu Higashiura, Nirasaki-shi (JP); Jack A. Gilmore, Fort Collins, CO (US); Joseph J. Osselburn, Mt. Laurel, NJ (US); Theresa Beizer, Cherry Hill, NJ (US)

Correspondence Address: OBLON, SPIVAK, MCCLELLAND, MAIER & NEUSTADT, P.C., 1940 DUKE STREET, ALEXANDRIA, VA, 22314, US

(73) Assignees: TOKYO ELECTRON LIMITED, Tokyo (JP); Advanced Engergy Industries, Inc., Fort Collins, CO (US)

(21) Appl. No.: 10/673,514

(22) Filed: Sep. 30, 2003

(51) Int. Cl. H01L 21/324; H01L 21/42

(52) U.S. Cl. 427/452

(57) ABSTRACT

A processing system having a processing chamber that includes a substrate holder and an electrode. The processing system can include a pressure control system, gas supply system, and monitoring system. A multi-frequency RF source is coupled to the electrode using a reduced-element matching network having a single variable element. The multi-frequency RF source is set to a first frequency to ignite a plasma and to a second frequency to maintain the plasma.

### BACKGROUND OF THE INVENTION

1. Field of the Invention

The present invention is related to semiconductor processing systems, particularly to a semiconductor processing system, which uses a variable frequency RF source.

2. Description of Related Art

The fabrication of integrated circuits (IC) in the semiconductor industry typically employs a plasma to create and assist surface chemistry within a plasma reactor necessary to remove material from and deposit material on a substrate. In general, a plasma is formed within the plasma reactor under vacuum conditions by heating electrons to energies sufficient to sustain ionizing collisions with a supplied process gas. Moreover, the heated electrons have energy sufficient to sustain dissociate collisions. Therefore, a specific set of gases under predetermined conditions (e.g., chamber pressure, gas flow rate, etc.) produce a population of charged species and chemically reactive species suitable to the particular process being performed within the chamber. For example, in etching processes energetic electrons in the plasma can initiate reactions with the process gas to create reactive species resulting in material removal from the substrate. As another example, in deposition processes energetic electrons in the plasma can initiate reactions with the process gas to create radical species resulting in deposition of materials on the substrate.

Typically, during plasma processing an RF source and a matching network are used to provide the energy required to ignite and sustain a plasma. In many applications, pi or T-type configurations are used having at least two tunable elements. This can cause these types of matching networks to be costly and large. A new type of matching network is required to overcome these shortcomings.

### SUMMARY OF THE INVENTION

Accordingly, it is one object of the present invention to provide a processing system having a reduced-element matching network and a method of operating a processing system utilizing a technique for optimal ignition having a reduced-element matching network.

This object and other objects of the present invention are accomplished in the different embodiments of the present invention.

In one aspect of the present invention, a method of operating a plasma processing system includes positioning a substrate on a substrate holder in a processing chamber, initializing the plasma processing system, igniting a plasma using a first signal at a first RF frequency such that a first frequency source is coupled to an electrode in the processing chamber, and sustaining the plasma using a second signal at a second RF frequency.

In another aspect of the present invention, a processing system includes a processing chamber having a substrate holder and an electrode configured above the substrate holder, a pressure control system coupled to the processing chamber, a gas supply system coupled to the processing chamber, and a reduced element matching network coupled to the processing chamber and coupled to the electrode. Further, the processing system includes a RF generator coupled to the reduced element matching network, and a control system coupled to the pressure control system, the gas supply system, the monitoring system, the matching network, and the RF generator.

In another aspect of the present invention, a computer readable medium containing program instructions for execution on a processor, which when executed by the processor, cause a plasma processing system to initialize the plasma processing system, supply a first signal at a first RF frequency to ignite a plasma via a first frequency source is coupled to an electrode in the processing chamber, and supply a second signal at a second RF frequency to sustain the plasma.

### BRIEF DESCRIPTION OF THE DRAWINGS

A more complete appreciation of the invention and many of the attendant advantages thereof will become readily apparent with reference to the following detailed description, particularly when considered in conjunction with the accompanying drawings, in which:

FIG. 1 is an exemplary block diagram of a processing system in accordance with one embodiment of the invention;

FIGS. 2A and 2B are exemplary schematics illustrating matching networks in accordance with one embodiment of the present invention;

FIG. 3 is a flow diagram illustrating a method of operating a processing system n accordance with one embodiment of the present invention;

FIG. 4 is a table of exemplary processing conditions and plasma states in accordance with one embodiment of the invention; and

FIG. 5 is a table of exemplary processing conditions and tuning times for the matching network in accordance with one embodiment of the invention.

FIG. 6 is an illustrative computer system for implementing various embodiments of the present invention.

### DETAILED DESCRIPTION OF THE PREFERRED EMBODIMENTS

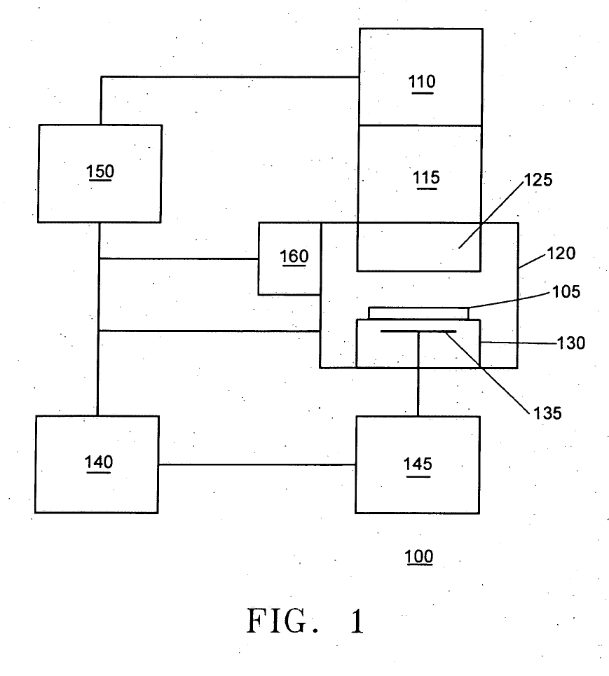

Referring now to the drawings, wherein like reference numerals designate identical, or corresponding parts throughout the several views, and more particularly to FIG. 1 thereof, FIG. 1 is an exemplary block diagram of a processing system in accordance with one embodiment of the present invention. The processing system 100 depicted in FIG. 1 can include an etch system, such as a plasma etcher. Alternately, the processing system 100 depicted in FIG. 1 can include a deposition system such as a chemical vapor deposition (CVD) system, a physical vapor deposition (PVD) system, an atomic layer deposition (ALD) system, and/or combinations thereof.

In one embodiment of the present invention, the processing system 100 includes a first RF source 110, a first matching network 115, processing chamber 120, monitoring system 160, and includes a second RF source 140, a second matching network 145, and controller 150. In addition, the processing chamber 120 can include a first electrode 125, a substrate holder 130, and a second electrode 135. Furthermore, processing system 100 can include a gas system (not shown) for providing a process gas to the processing chamber 120, and a pressure control system (not shown) for controlling the chamber pressure. In the illustrated embodiment, a single processing chamber 120 is shown, but the invention is not so limited.

As shown in FIG. 1, a substrate 105 can be processed in the processing chamber 120. For example, substrate 105 can be transferred into and out of processing chamber 120 through a slot valve (not shown) and chamber feed-through (not shown) via robotic substrate transfer system (not shown) where it can be received by substrate lift pins (not shown) housed within substrate holder 130 and mechanically translated by devices housed therein. Once substrate 135 is received from substrate transfer system, it can be lowered to an upper surface of substrate holder 130.

In addition, substrate holder 130 can include an electrostatic clamping system (not shown) for clamping substrate 105. Furthermore, substrate holder 130 can further include a temperature control means (not shown). Moreover, gas can, for example, be delivered to the backside of substrate 105 via a backside gas system to improve the gas-gap thermal conductance between substrate 105 and substrate holder 130. Such a system can be utilized when temperature control of the substrate is required at elevated or reduced temperatures. In other embodiments, heating elements, such as resistive heating elements, or thermoelectric heaters/coolers can be included.

In one embodiment of the present invention, the first RF source 110 is coupled to the first matching network 115. For example, the first RF source 110 can be coupled directly to the first matching network 115. In an alternate embodiment, a short transmission line (e.g., a transmission line less than 10 cm in length) can be used to couple the first RF source to the first matching network. The first RF source can be a high power VHF source such as a RF Generator (VHF-5060) from Advanced Energy Industries, Inc.

The first matching network 115 can be coupled to the processing chamber 120 and the first electrode 125. For example, the first matching network 115 can be mounted on the processing chamber 120, as shown in the illustrated embodiment with the first matching network 115 on top of the processing chamber 120. In an alternate embodiment, a short transmission line (e.g., a transmission line less than 31 cm in length) can be used to couple the first matching network to the processing chamber. The first matching network 115 can be for example a high power matching network similar to those commercially available from Advanced Energy Industries, Inc.

In one embodiment of the present invention, the second RF source 140 is coupled to the second matching network 145. For example, the second RF source 140 can be coupled to the second matching network 145 using a transmission line. This allows the second RF source to be located for example outside a clean room. The second RF source can be a high power source, such as for example the RF Generator HFV-8000 from Advanced Energy Industries, Inc.

The second matching network 145 can be coupled to the processing chamber 120 and the second electrode 135. In the illustrated embodiment, the second matching network 115 is coupled to processing chamber 120 and second electrode 135 using at least one cable, but this is not required for the invention. Alternately, the second matching network can be coupled in other configurations known to those skilled in the art.

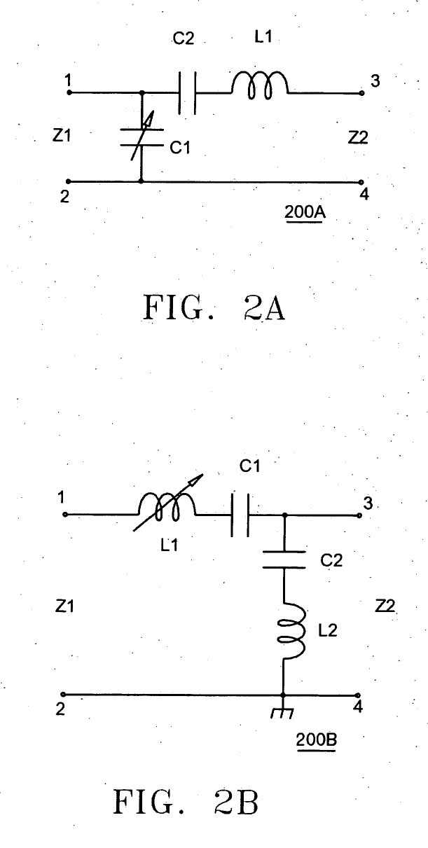

FIGS. 2A and 2B illustrate exemplary schematics for matching networks in accordance with different embodiments of the present invention.

In the illustrated embodiment shown in FIG. 2A, matching network 200A includes a variable capacitor C1, a fixed capacitor C2, and an inductor L1. An input impedance Z1 exists between input terminals 1 and 2, and an output impedance Z2 exists between output terminals 3 and 4. Terminal 2 is shown coupled to terminal 4. For example, terminal 2 and terminal 4 can be coupled to ground. In addition, the variable capacitor C1 is shown coupled between input terminal 1 and input terminal 2. The fixed capacitor C2 is shown having a first end coupled to terminal 1 and one terminal of C1, and a second end coupled to a first end of L1. Furthermore, the second end of L1 is shown coupled to terminal 3. The illustrated matching network is advantageous because it includes a single inductive element and a single variable capacitor. The present invention is less costly to produce and more reliable because it requires a single variable capacitor.

This configuration can be used as a matching network where Z1 is the source impedance for the first RF generator and Z2 is the impedance at the top electrode with and/or without plasma. In one example, C1 can have a capacitance value that ranges from approximately 20 pf to approximately 200 pf, C2 can have a capacitance value of approximately 30 pf (i.e. in a range from approximately 20 pf to approximately 75 pf), and L1 can have an inductance value of approximately 120 nanohenries, assuming an operating frequency of approximately 60 MHz. In alternate embodiments, different capacitance values, different inductance values, and operating frequencies can be used to provide matching between the input and output impedance.

In the illustrated embodiment shown in FIG. 2B, matching network 200B includes a variable inductor L1, a fixed capacitor C1, a fixed capacitor C2, and an inductor L2. Also, an input impedance Z1 exists between input terminals 1 and 2, and an output impedance Z2 exists between output terminals 3 and 4. For example, terminal 2 can be coupled to terminal 4, and terminal 2 and terminal 4 can be coupled to ground. A first end of the variable inductor L1 is shown coupled to terminal 1, and a second end of the variable inductor L1 is shown coupled to a first end of C1. In addition, a second end of capacitor C1 is shown coupled to a first end of the capacitor C2 and to output terminal 2. The second end of capacitor C2 is shown coupled to a first end of L2. Furthermore, the second end of L2 is shown coupled to terminal 2 and terminal 4. The illustrated matching network is advantageous because it comprises a single variable element. The present invention is less costly to produce and more reliable because it requires a single variable inductor.

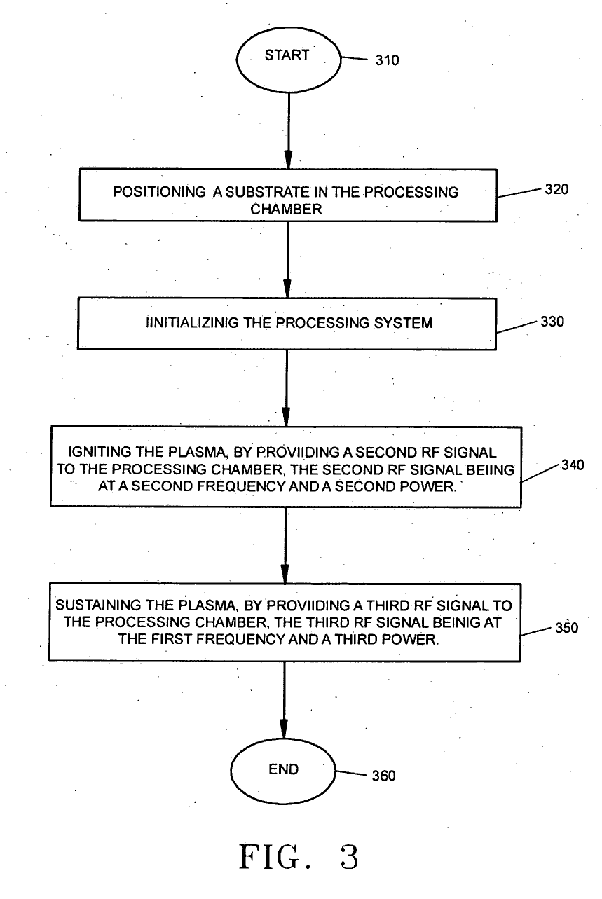

FIG. 3 illustrates a flow diagram for a method of operating a processing system according to the present invention. The procedure starts in step 310.

In step 320, a substrate is positioned in the processing chamber. For example, a transfer system can be used to move a substrate in and out of the processing chamber. The transfer system can position the substrate over the substrate holder. Lift pins in the substrate holder can be used to lower the substrate to the upper surface of the substrate holder. An electrostatic clamp can be used to hold the substrate in position on the substrate holder.

In step 330, the processing system is initialized. For example, process gas can be introduced into the processing chamber, and a chamber pressure can be established. While the present invention is not restricted to certain process gases, a process gas can include at least one of a carbon-containing gas, an oxygen-containing gas, a fluorine-containing gas, and an inert gas. While the present invention is not restricted to certain process pressures, a chamber pressure can be less than 0.5 Torr.

In addition, the first matching network can be tuned to an initial value, the first RF source can provide a first top RF (TRF) signal to the first electrode in the processing chamber. The first TRF signal can be characterized by a first TRF frequency (TRF1) and a first TRF power level.

Furthermore, the second matching network can be tuned also to an initial value, the second RF source can provide a first bottom RF (BRF) signal to the second electrode in the processing chamber. The first BRF signal can be characterized by a first BRF frequency (BRF1) and a first BRF power level.

In step 340, after a plasma is ignited, the first RF source provides a second TRF signal to the first electrode in the processing chamber. The second TRF signal can be characterized by a second TRF frequency (TRF2) and a second TRF power level.

For example, the first RF source can perform a frequency step from TRF1 to TRF2. In one embodiment of the present invention, the frequency step can be at least ten percent of the first frequency. In other words, TRF2 can be greater than 1.1×(TRF1) or less than 0.9×(TRF1). In another embodiment, the frequency step can be at least two percent of the first frequency. In other words, TRF2 can be greater than 1.02×(TRF1) or less than 0.98×(TRF1).

Preferably, the second TRF power level can be greater than fifty percent of the first TRF power level. Lower power output requirement for the second TRF power level permits the RF frequency source to be less expensive.

In one embodiment of the present invention, the frequency step can have a duration that ranges from approximately ten milliseconds to approximately one second. Longer duration steps can allow the RF frequency source to be less expensive to manufacture.

In an alternate embodiment of the present invention, the frequency source can be stepped from TRF1 to TRF2. For example, the frequency source can be stepped linearly from TRF1 to TRF2.

In the illustrated embodiment shown in FIG. 1, a monitoring system is shown, and the monitoring system can be used to determine if the plasma has been ignited. When a plasma is ignited, the RF frequency source is stepped back from TRF2 to TRF1.

When a plasma is not ignited, a fault condition can be established. For example, the process can be paused, and a message can be sent.

In another embodiment of the present invention, the plasma ignition process can be performed again, when a plasma is not ignited. For example, the ignition process can be performed a number of times before a fault condition is established.

In step 350, the plasma is sustained by providing a third RF signal to the processing chamber. The third RF signal can be at the first frequency and a third power. For example, the third power can be approximately equal to the first power. Alternately, the third RF signal can be at a different frequency and/or a different power.

In addition, a monitoring system, such as shown in FIG. 1, can be used to determine if the plasma is being sustained. When the plasma is sustained, the procedure ends at step 360.

When a plasma is not sustained, a fault condition can be established. For example, the process can be paused, and a message can be sent.

In another embodiment, the plasma ignition process can be performed again, when a plasma is not sustained. For example, the ignition process can be performed a number of times before a fault condition is established.

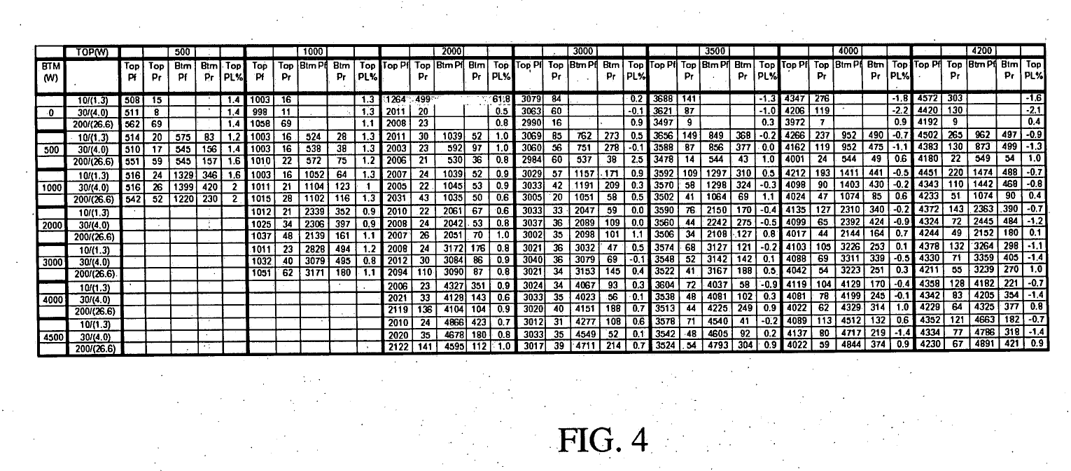

FIG. 4 illustrates a table of exemplary processing conditions and plasma state in accordance with one embodiment of the invention. For example, the data shows that a frequency step from 68 MHz to 60 MHz caused a plasma to be ignited and sustained in nearly all of the tests. The RF frequency used here is preferably greater than approximately 40.0 MHz. Tests were performed at low pressure (10 mTorr), medium pressure (30 mTorr), and high pressure (200 mTorr) using TRF signal powers from 500 watts to 4200 watts and BRF signal powers from 0 watts to 4500 watts. The table shows the accuracy of the load power for the matching network after tuning. The Top PL % is the accuracy of the load power and is equal to (1−((Top Pf−Top Pr)/(TRF power setting))×100), where Top Pf is the forward power at the top electrode, Top Pr is the reflected power at the top electrode, and TRF power setting is the RF generator power setting. The data shows that the system of the present invention operates for a TRF power of at least 450 watts and a chamber pressure that is less than 0.5 Torr.

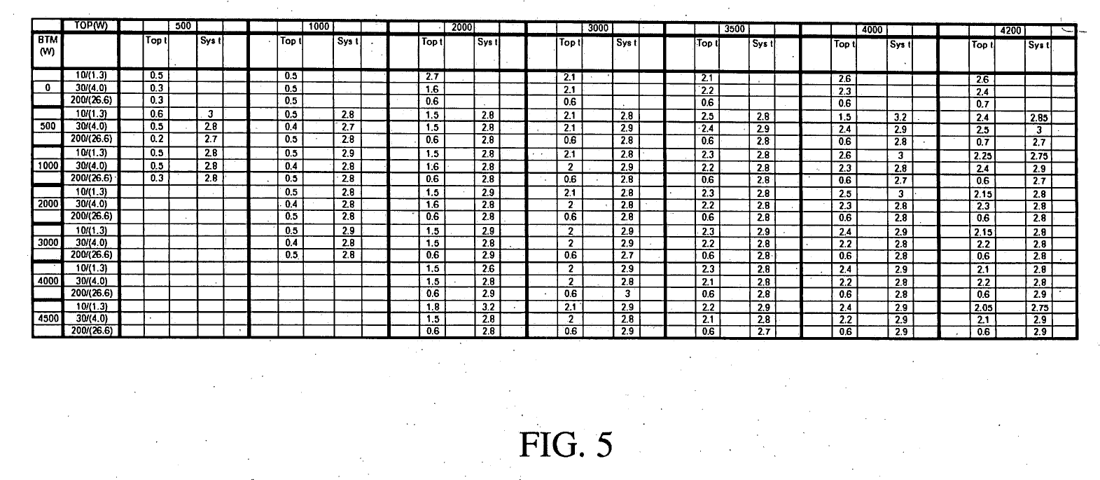

FIG. 5 illustrates a table of exemplary processing conditions and tuning time for the matching network in accordance with another embodiment of the invention. The table shows the results for a top electrode tuning time (Top t) and for a system tuning time (Sys t). The data shows that the matching network is able to tune from its initial value to an operating value in less than three seconds in nearly all of the tests. Tests were performed at low pressure (10 mTorr), medium pressure (30 mTorr), and high pressure (200 mTorr) using TRF signal powers from 500 watts to 4200 watts and BRF signal powers from 0 watts to 4500 watts.

In one embodiment of the present invention, a monitoring system 160 is coupled to the processing chamber 120. For example, the processing chamber 120 can include at least one window (not shown) that is substantially transparent to light at a wavelength emitted by a plasma in the processing chamber 120, and the monitoring system can use such a window to provide diagnostics on the plasma.

In one embodiment of the present invention, the controller 150 can be configured to send and/or receive data to/from the processing system 100. For example, controller 150 can include a microprocessor, a memory (e.g., volatile and/or non-volatile memory), and an analog I/O port capable of generating control voltages sufficient to communicate and activate inputs to the processing system 100 as well as monitor outputs from the processing system 100. Moreover, the controller 150 can exchange information with the first RF source 110, the first matching network 115, the processing chamber 120, the substrate holder 130, the second RF source 140, the second matching network 145, and the monitoring system 160. In addition, a program stored in the memory can be utilized to control the aforementioned components of a processing system 100 according to a process recipe. In addition, the controller 150 can be configured to collect data (process data and system data), to analyze the data, to compare the data with target data, and to use the comparison to change a process and/or control one or more components of the processing system. Also, the controller can be configured to analyze the data, to compare the data with historical data, and to use the comparison to predict, prevent, and/or declare a fault.

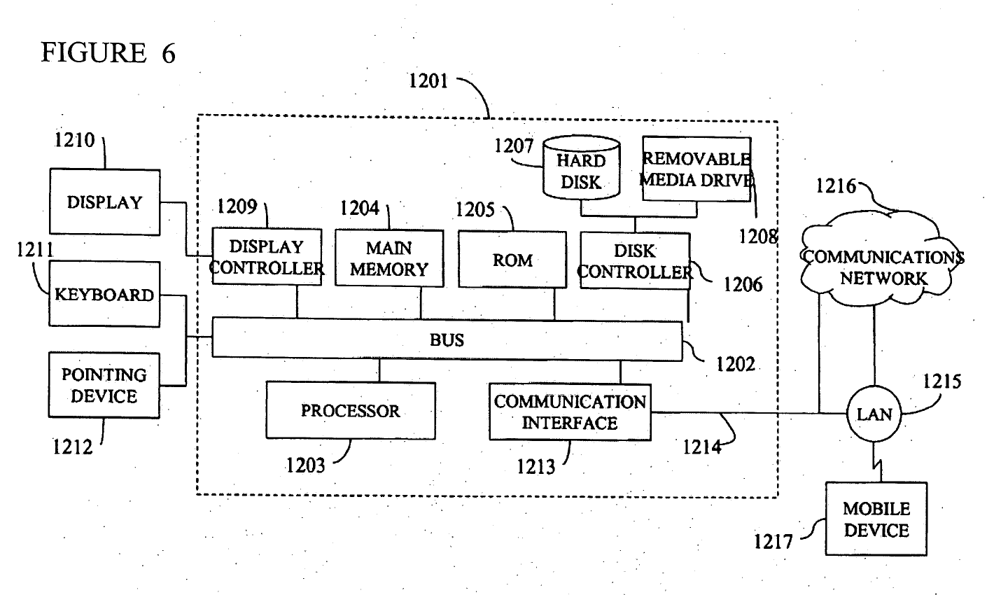

FIG. 6 illustrates a computer system 1201 for implementing various embodiments of the present invention. The computer system 1201 may be used as the controller 150 or the monitoring system 160 to perform any or all of the functions of described above. The computer system 1201 includes a bus 1202 or other communication mechanism for communicating information, and a processor 1203 coupled with the bus 1202 for processing the information. The computer system 1201 also includes a main memory 1204, such as a random access memory (RAM) or other dynamic storage device (e.g., dynamic RAM (DRAM), static RAM (SRAM), and synchronous DRAM (SDRAM)), coupled to the bus 1202 for storing information and instructions to be executed by processor 1203. In addition, the main memory 1204 may be used for storing temporary variables or other intermediate information during the execution of instructions by the processor 1203. The computer system 1201 further includes a read only memory (ROM) 1205 or other static storage device (e.g., programmable ROM (PROM), erasable PROM (EPROM), and electrically erasable PROM (EEPROM)) coupled to the bus 1202 for storing static information and instructions for the processor 1203. The computer system may also include one or more digital signal processors (DSPs) such as the TMS320 series of chips from Texas Instruments, the DSP56000, DSP56100, DSP56300, DSP56600, and DSP96000 series of chips from Motorola, the DSP1600 and DSP3200 series from Lucent Technologies or the ADSP2100 and ADSP21000 series from Analog Devices. Other processors specially designed to process analog signals that have been converted to the digital domain may also be used.

The computer system 1201 also includes a disk controller 1206 coupled to the bus 1202 to control One or more storage devices for storing information and instructions, such as a magnetic hard disk 1207, and a removable media drive 1208 (e.g., floppy disk drive, read-only compact disc drive, read/write compact disc drive, compact disc jukebox, tape drive, and removable magneto-optical drive). The storage devices may be added to the computer system 1201 using an appropriate device interface (e.g., small computer system interface (SCSI), integrated device electronics (IDE), enhanced-IDE (E-IDE), direct memory access (DMA), or ultra-DMA).

The computer system 1201 may also include special purpose logic devices (e.g., application specific integrated circuits (ASICs)) or configurable logic devices (e.g., simple programmable logic devices (SPLDs), complex programmable logic devices (CPLDs), and field programmable gate arrays (FPGAs)).

The computer system 1201 may also include a display controller 1209 coupled to the bus 1202 to control a display 1210, such as a cathode ray tube (CRT), for displaying information to a computer user. The computer system includes input devices, such as a keyboard 1211 and a pointing device 1212, for interacting with a computer user and providing information to the processor 1203. The pointing device 1212, for example, may be a mouse, a trackball, or a pointing stick for communicating direction information and command selections to the processor 1203 and for controlling cursor movement on the display 1210. In addition, a printer may provide printed listings of data stored and/or generated by the computer system 1201.

The computer system 1201 performs a portion or all of the processing steps of the invention (such as for example those described in relation to FIG. 12) in response to the processor 1203 executing one or more sequences of one or more instructions contained in a memory, such as the main memory 1204. Such instructions may be read into the main memory 1204 from another computer readable medium, such as a hard disk 1207 or a removable media drive 1208. One or more processors in a multi-processing arrangement may also be employed to execute the sequences of instructions contained in main memory 1204. In alternative embodiments, hard-wired circuitry may be used in place of or in combination with software instructions. Thus, embodiments are not limited to any specific combination of hardware circuitry and software.

As stated above, the computer system 1201 includes at least one computer readable medium or memory for holding instructions programmed according to the teachings of the invention and for containing data structures, tables, records, or other data described herein. Examples of computer readable media are compact discs, hard disks, floppy disks, tape, magneto-optical disks, PROMs (EPROM, EEPROM, flash EPROM), DRAM, SRAM, SDRAM, or any other magnetic medium, compact discs (e.g., CD-ROM), or any other optical medium, punch cards, paper tape, or other physical medium with patterns of holes, a carrier wave (described below), or any other medium from which a computer can read.

Stored on any one or on a combination of computer readable media, the present invention includes software for controlling the computer system 1201, for driving a device or devices for implementing the invention, and for enabling the computer system 1201 to interact with a human user (e.g., print production personnel). Such software may include, but is not limited to, device drivers, operating systems, development tools, and applications software. Such computer readable media further includes the computer program product of the present invention for performing all or a portion (if processing is distributed) of the processing performed in implementing the invention.

The computer code devices of the present invention may be any interpretable or executable code mechanism, including but not limited to scripts, interpretable programs, dynamic link libraries (DLLs), Java classes, and complete executable programs. Moreover, parts of the processing of the present invention may be distributed for better performance, reliability, and/or cost.

The term “computer readable medium” as used herein refers to any medium that participates in providing instructions to the processor 1203 for execution. A computer readable medium may take many forms, including but not limited to, non-volatile media, volatile media, and transmission media. Non-volatile media includes, for example, optical, magnetic disks, and magneto-optical disks, such as the hard disk 1207 or the removable media drive 1208. Volatile media includes dynamic memory, such as the main memory 1204. Transmission media includes coaxial cables, copper wire and fiber optics, including the wires that make up the bus 1202. Transmission media also may also take the form of acoustic or light waves, such as those generated during radio wave and infrared data communications.

Various forms of computer readable media may be involved in carrying out one or more sequences of one or more instructions to processor 1203 for execution. For example, the instructions may initially be carried on a magnetic disk of a remote computer. The remote computer can load the instructions for implementing all or a portion of the present invention remotely into a dynamic memory and send the instructions over a telephone line using a modem. A modem local to the computer system 1201 may receive the data on the telephone line and use an infrared transmitter to convert the data to an infrared signal. An infrared detector coupled to the bus.1202 can receive the data carried in the infrared signal and place the data on the bus 1202. The bus 1202 carries the data to the main memory 1204, from which the processor 1203 retrieves and executes the instructions. The instructions received by the main memory 1204 may optionally be stored on storage device 1207 or 1208 either before or after execution by processor 1203.

The computer system 1201 also includes a communication interface 1213 coupled to the bus 1202. The communication interface 1213 provides a two-way data communication coupling to a network link 1214 that is connected to, for example, a local area network (LAN) 1215, or to another communications network 1216 such as the Internet. For example, the communication interface 1213 may be a network interface card to attach to any packet switched LAN. As another example, the communication interface 1213 may be an asymmetrical digital subscriber line (ADSL) card, an integrated services digital network (ISDN) card or a modem to provide a data communication connection to a corresponding type of communications line. Wireless links may also be implemented. In any such implementation, the communication interface 1213 sends and receives electrical, electromagnetic or optical signals that carry digital data streams representing various types of information.

The network link 1214 typically provides data communication through one or more networks to other data devices. For example, the network link 1214 may provide a connection to another computer through a local network 1215 (e.g., a LAN) or through equipment operated by a service provider, which provides communication services through a communications network 1216. The local network 1214 and the communications network 1216 use, for example, electrical, electromagnetic, or optical signals that carry digital data streams, and the associated physical layer (e.g., CAT 5 cable, coaxial cable, optical fiber, etc). The signals through the various networks and the signals on the network link 1214 and through the communication interface 1213, which carry the digital data to and from the computer system 1201 maybe implemented in baseband signals, or carrier wave based signals. The baseband signals convey the digital data as unmodulated electrical pulses that are descriptive of a stream of digital data bits, where the term “bits” is to be construed broadly to mean symbol, where each symbol conveys at least one or more information bits. The digital data may also be used to modulate a carrier wave, such as with amplitude, phase and/or frequency shift keyed signals that are propagated over a conductive media, or transmitted as electromagnetic waves through a propagation medium. Thus, the digital data may be sent as unmodulated baseband data through a “wired” communication channel and/or sent within a predetermined frequency band, different than baseband, by modulating a carrier wave. The computer system 1201 can transmit and receive data, including program code, through the network(s) 1215 and 1216, the network link 1214, and the communication interface 1213. Moreover, the network link 1214 may provide a connection through a LAN 1215 to a mobile device 1217 such as a personal digital assistant (PDA) laptop computer, or cellular telephone.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention. It is therefore to be understood that within the scope of the appended claims, the invention may be practiced otherwise than as specifically described herein.

1. A method of operating a plasma processing system, comprising:
positioning a substrate on a substrate holder in a processing chamber;
initializing the plasma processing system;
igniting a plasma using a first signal at a first RF frequency, wherein a first frequency source is coupled to an electrode in the processing chamber; and
sustaining the plasma using a second signal at a second RF frequency.

2. The method as claimed in claim 1, further comprising:
establishing a first power level for the first signal, wherein the first signal is set to a first output power level.

3. The method as claimed in claim 2, wherein the first power level is at least 50 Watts.

4. The method as claimed in claim 1, further comprising:
introducing the process gas into the processing chamber, wherein the process gas comprises at least one of a carbon-containing gas, an oxygen-containing gas, a fluorine-containing gas, and an inert gas; and
establishing the chamber pressure below approximately 0.5 Torr.

5. The method as claimed in claim 1, further comprising:
coupling the first frequency source to the electrode of the plasma processing system using a first matching network; and
tuning the first matching network to an initial condition for plasma ignition.

6. The method as claimed in claim 1, wherein the first RF frequency is at least two percent higher in frequency than the second RF frequency.

7. The method as claimed in claim 1, wherein the first RF frequency is at least ten percent higher in frequency than the second RF frequency.

8. The method as claimed in claim 1, wherein the first RF frequency is greater than approximately 40.0 MHz.

9. The method as claimed in claim 1, wherein the first RF frequency is at least two percent lower in frequency than the second RF frequency.

10. The method as claimed in claim 1, wherein the first RF frequency is at least ten percent lower in frequency than the second RF frequency.

11. The method as claimed in claim 1, wherein the first signal is provided for a first time period, and the second signal is provided for a second time period.

12. The method as claimed in claim 11, wherein the first time period has a duration that ranges from approximately ten milliseconds to approximately one second.

13. The method as claimed in claim 1, further comprising:
determining a forward power for the first signal being provided by the first frequency source;
determining a reflected power for the first signal being returned to the first frequency source; and
determining when the plasma has been ignited using at least one of the forward power and the reflected power.

14. The method as claimed in claim 5, further comprising:
determining a forward power for the first signal being provided by the first frequency source;
determining a reflected power for the first signal being returned to the first frequency source; and
determining when the plasma has been ignited using at least one of the forward power and the reflected power.

15. The method as claimed in claim 1, further comprising:
monitoring the processing chamber by a monitoring system coupled to the processing chamber to monitor optical frequencies in the processing chamber; and
determining when the plasma has been ignited using at least one optical frequency.

16. The method as claimed in claim 1, comprising:
monitoring the processing chamber by a monitoring system coupled to the processing chamber to monitor optical frequencies in the processing chamber; and
determining that the plasma has been sustained using at least one optical frequency.

17. The method as claimed in claim 5, further comprising:
tuning the first matching network from the initial condition to an operating condition; and
verifying that the plasma has not extinguished.

18. The method as claimed in claim 17, wherein the first matching network is tuned from the initial condition to the operating condition in less than 4 seconds.

19. The method as claimed in claim 1, further comprising:
coupling a second RF source to a second electrode in the processing chamber; and
providing additional power to the plasma.

20. A processing system comprising:
a processing chamber having a substrate holder and an electrode configured above the substrate holder;
a pressure control system coupled to the processing chamber;
a gas supply system coupled to the processing chamber;
a reduced element matching network coupled to the processing chamber and coupled to the electrode;
a RF generator coupled to the reduced element matching network; and
a control system coupled to the pressure control system, the gas supply system, the monitoring system, the matching network, and the RF generator.

21. The processing system as claimed in claim 20, wherein the reduced element matching network comprises an input terminal, an output terminal, a common terminal, a tunable element coupled between the input terminal and the common terminal, and a fixed element coupled between the input terminal and the output terminal.

22. The processing system as claimed in claim 21, wherein the reduced element matching network further comprises a tuning adjustment device coupled to the tunable element wherein the tuning adjustment device is coupled to the control system and the control system provides signals to the tuning adjustment device and receives signals from the tuning adjustment device.

23. The processing system as claimed in claim 21, wherein the tunable element comprises a variable capacitor.

24. The processing system as claimed in claim 23, wherein the variable capacitor has a tuning range from approximately 5 pf to approximately 250 pf.

25. The processing system as claimed in claim 21, wherein the fixed reactive element comprises a fixed capacitor.

26. The processing system as claimed in claim 25, wherein the fixed capacitor has a capacitance value in a range from approximately 20 pf to approximately 75 pf.

27. The processing system as claimed in claim 20, wherein the reduced element matching network comprises an input terminal, an output terminal, and a common terminal, the RF generator being coupled to the input terminal and the common terminal, the electrode being coupled to the output terminal, and the processing chamber being coupled to the common terminal.

28. The processing system as claimed in claim 20, wherein the RF generator is configured to operate at a first frequency during a first time period and is configured to operate at a second frequency during a second time period.

29. The processing system as claimed in claim 28, wherein the first frequency is at least two percent higher in frequency than the second frequency.

30. The processing system as claimed in claim 28, wherein the first frequency is at least ten percent higher in frequency than the second frequency.

31. The processing system as claimed in claim 28, wherein the second frequency is greater than or equal to approximately 40 MHz.

32. The processing system as claimed in claim 28, wherein the first time period has a duration that ranges from approximately ten milliseconds to approximately one second.

33. The processing system as claimed in claim 28, wherein the RF generator is configured to provide a first output power during the first time period and a second output power during the second time period.

34. The processing system as claimed in claim 33, wherein the first output power is at least fifty percent of the second output power.

35. The processing system as claimed in claim 20, wherein the monitoring system comprises:
a sensor coupled to the RF generator, the sensor providing forward power data and reflected power data to the control system, and the control system is configured to determine processing conditions using the forward power data and reflected power data.

36. The processing system as claimed in claim 35, wherein the control system is configured to use the forward power data and the reflected power data to determine when a plasma has been ignited.

37. The processing system as claimed in claim 35, wherein the control system is configured to use the forward power data and the reflected power data to determine when a plasma is stable.

38. The processing system as claimed in claim 20, wherein the monitoring system comprises:
an optical sensor coupled to the processing chamber, the optical sensor providing optical data to the control system, and the control system is configured to determine processing conditions using the optical data.

39. The processing system as claimed in claim 38, wherein the control system is configured to use the optical data to determine when a plasma has been ignited.

40. The processing system as claimed in claim 38, wherein the control system is configured to use the optical data to determine when a plasma is stable.

41. The processing system as claimed in claim 20, further comprising:
a second electrode coupled to the substrate holder;
a second matching network coupled to the second electrode; and
a second RF generator coupled to the second matching network.

42. The processing system as claimed in claim 41, wherein the second RF generator is configured to provide a first BRF signal to the second electrode.

43. The processing system as claimed in claim 20, wherein the reduced element matching network is mounted above the electrode, and a first transmission line is used to couple the matching network to the electrode.

44. The processing system as claimed in claim 43, wherein the first transmission line is less than 10 cm.

45. The processing system as claimed in claim 43, wherein the RF generator is mounted above the matching network, and a second transmission line is used to couple the RF generator to the matching network.

46. The processing system as claimed in claim 45, wherein the second transmission line is less than 31 cm.

47. The processing system as claimed in claim 20, further comprising:
a monitoring system coupled to the processing chamber.

48. A computer readable medium containing program instructions for execution on a processor, which when executed by the processor, cause a plasma processing system to perform the steps of:
initializing the plasma processing system;
supplying a first signal at a first RF frequency to ignite a plasma, wherein a first frequency source is coupled to an electrode in the processing chamber; and
supplying a second signal at a second RF frequency to sustain the plasma.

49. A plasma processing system comprising:
means for initializing the plasma processing system;
means for supplying a first signal at a first RF frequency to ignite a plasma, said means for supplying coupling said first signal to an electrode in the processing chamber; and
means for supplying a second signal at a second RF frequency to sustain the plasma.
